(19) United States
(12) Patent Application Publication
(10) Pub. No.: US 2007/0068628 A1
(43) Pub. Date: Mar. 29, 2007

(54) Vacuum processing apparatus

(76) Inventors: Takeo Uchino, Kudamatsu-shi (JP); Tsutomu Nakamura, Hikari-shi (JP); Michiaki Kobayashi, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/362,868

(22) Filed: Feb. 28, 2006

(30) Foreign Application Priority Data
Sep. 28, 2005 (JP) 2005-281067

(51) Int. Cl. H01L 21/306; C23C 16/00

(52) U.S. Cl. 156/345.32; 118/719

(57) ABSTRACT

A vacuum processing apparatus having an improved wafer processing efficiency and an improved working efficiency is provided. The vacuum processing apparatus includes a vacuum container in which a specimen is processed with plasma generated from a processing gas supplied to the vacuum container; a transfer container through which the specimen processed in the vacuum container is transferred, the transfer container being coupled to the vacuum container under ambient pressure; a blower for generating an ambient gas flow in the transfer container and an outlet disposed on the transfer container; a storage container for storing the specimen processed in the vacuum container, the storage container being disposed in the ambient gas flow in the transfer container; and an exhauster for exhausting a gas in the storage container.

The present application is based on and claims priority of Japanese patent application No. 2005-281067 filed on Sep. 28, 2005, the entire contents of which are hereby incorporated by reference.

### BACKGROUND OF THE INVENTION

1. Field of the Invention

The present invention relates to a vacuum processing apparatus in which a wafer in a cassette is transferred to a vacuum container and is processed with plasma in a processing chamber in the vacuum container, and more particularly to a vacuum processing apparatus including an atmospheric transfer chamber in which a wafer is transferred between the cassette and a transfer container or a buffer chamber connected to the vacuum container.

2. Description of the Related Art

In such an apparatus, in particular, in a vacuum processing apparatus in which a semiconductor wafer substrate is processed in a low-pressure unit, there has been a growing demand for higher processing efficiency as well as finer and more precise processing. To this end, a multi-chamber apparatus including a plurality of processing chambers has been developed in recent years. In the multi-chamber apparatus, a wafer is subjected to a plurality of process steps to increase the processing efficiency.

In such a processing apparatus including a plurality of processing chambers, each processing chamber is connected to a transfer chamber that includes a robot arm for transferring a wafer and the internal gas pressure of which can be decreased.

In such a structure, a wafer is transferred from one processing chamber to another processing chamber before or after processing through a low-pressure transfer chamber or a transfer chamber filled with an inert gas. Thus, a wafer is processed continuously without being exposed to the outside air. This prevents the wafer from being contaminated and increases the process yield or the processing efficiency.

Such a structure can also eliminate or shorten time to increase or decrease the internal pressure of a processing chamber or a transfer chamber. This reduces the number of procedures and savings time and effort to process the wafer, thus increasing processing efficiency.

In another conventional vacuum processing apparatus including a plurality of chambers, a vacuum transfer container including a transfer unit is surrounded by a load lock chamber or an unload lock chamber and a plurality of processing containers for different required processes. A specimen is transferred between the processing containers through an atmospheric transfer chamber connected to the load lock chamber or the unload lock chamber. This increases the processing efficiency.

In such a vacuum processing apparatus, a wafer as a specimen in a cassette under atmospheric pressure is taken out of the cassette, for example, with a transfer robot installed in an atmospheric transfer chamber. The cassette is transferred to a load lock chamber through the atmospheric transfer chamber. After an opening of the load lock chamber is closed, the load lock chamber is evacuated to substantially the same pressure as the internal pressure of a vacuum transfer container or a processing container. After the evacuation is completed, a valve to the vacuum transfer container is opened. Then, the specimen is removed from the load lock chamber with a robot arm in the processing container and is transferred to a specimen stage in the processing container. After a valve between the processing container and the vacuum transfer container is closed, the specimen is processed in the processing container. Then, the valve is opened and the specimen is removed from the processing container with the robot arm. The specimen is transferred to another processing container for another processing or is returned into the cassette in reverse order to that described above.

In an apparatus that can process wafers simultaneously in a plurality of processing containers, a wafer is processed in one processing container and is then processed in another processing container for another processing (sequential process), or different wafers are subjected to the same or different processes in a plurality of processing containers (parallel process). Furthermore, in the sequential process of a wafer, one wafer can be subjected to a first process in one processing container while another wafer is subjected to a second process in another processing container.

In a known vacuum processing apparatus, a controller or a user of the apparatus can select the processing schedule, including the transfer of a wafer, on the basis of the type of wafer to be processed, the process requirements, or the number of wafers to be processed. Such a conventional technology is disclosed in Japanese Unexamined Patent Application Publication No. 2001-093791.

In general, a wafer processed in a processing container is returned into an original position in an original cassette. However, a processed wafer is accompanied by a reactive or corrosive gas or product used in processing. Thus, returning a processed wafer into an original cassette in which an unprocessed wafer is placed may have adverse effects to the unprocessed wafer.

Hence, in another conventional apparatus, in addition to a wafer cassette disposed on the periphery of the apparatus, another wafer cassette is disposed within the apparatus. Thus, all or part of wafers to be processed are transferred from the outside cassette, while a processed wafer is returned to the outside cassette, or processed wafers are stored in the inside cassette temporarily and transferred to the outside cassette when no unprocessed wafer is left in the outside cassette.

Such structures are found in Japanese Unexamined Patent Application Publication No. 6-005688 and Japanese Unexamined Patent Application Publication No. 2002-043292.

Such conventional technologies lack consideration for the following and thereby have caused problems.

For example, when a plurality of wafers are transferred from wafer cassettes disposed in an atmospheric transfer chamber to processing containers and are simultaneously subjected to the same processing in processing chambers in the processing containers, if the apparatus has only one inside cassette, the inside cassette cannot store all the wafers. Thus, the processing efficiency is decreased.

Furthermore, in the conventional technologies described above, wafers are processed in at least two processing containers. If something unusual occurs and one wafer cannot be processed in a processing chamber in a processing container, a reduction in capacity utilization can be minimized by adjusting the processing schedule in a manner such that the wafer is processed in another normal processing container. However, after an etching process, a wafer is directly taken out and the processing container is opened to the atmosphere. Thus, a processed wafer accompanied by a reactive gas or a reaction product has adverse effects on neighboring components and another wafer. This is not taken into consideration in the conventional technologies.

In other words, after an etching process, a residual gas or product on and around a processed wafer stored in a cassette, such as a front opening unified pod (FOUP), contaminates an unprocessed wafer in the same cassette. Furthermore, foreign matter derived from a halogen gas acts as a mask during etching and thereby causes an etching residue, thus decreasing the process yield. The conventional technologies do not take these into consideration. In addition, the residual gas is difficult to remove completely from a wafer. The resulting increased concentration of gas or product in the cassette, such as FOUP, may adversely affect the environment. The conventional technologies also do not take this into consideration.

Installation of such a cassette in a load lock chamber undesirably makes the structure of the load lock chamber complicated or increases the volume of the load lock chamber and the footprint of the whole apparatus. Even in an apparatus including such a cassette in an atmospheric transfer chamber or a vacuum transfer chamber, to ensure a working space of a wafer transfer robot or a space required for the wafer transfer is not considered. Thus, a cassette installed outside of a transfer container causes an increase in footprint and a reduction in maintenance space. This results in a decrease in working efficiency, which in turn decreases processing efficiency.

### SUMMARY OF THE INVENTION

Accordingly, it is an object of the present invention to provide a vacuum processing apparatus having an improved wafer processing efficiency and an improved working efficiency.

The object can be achieved with a vacuum processing apparatus including a vacuum container in which a specimen is processed with plasma generated from a processing gas supplied to the vacuum container; a transfer container through which the specimen processed in the vacuum container is transferred, the transfer container being coupled to the vacuum container under ambient pressure; a blower for generating an ambient gas flow in the transfer container and an outlet disposed on the transfer container; a storage container for storing the specimen processed in the vacuum container, the storage container being disposed in the ambient gas flow in the transfer container; and an exhauster for exhausting a gas in the storage container.

In another aspect of the present invention, a vacuum processing apparatus includes a vacuum container in which a specimen is processed with plasma generated from a processing gas supplied to the vacuum container; a transfer container through which the specimen processed in the vacuum container is transferred, the transfer container being coupled to the vacuum container under ambient pressure; a stage on which the specimen is placed, the stage being disposed outside the transfer container; a robot for putting the specimen into and removing the specimen from a cassette that stores the specimen and for transferring the specimen in the transfer container, the robot being disposed in the transfer container and the cassette being disposed on the stage; a blower for generating an ambient gas flow in the transfer container and an outlet disposed on the transfer container; a storage container for storing the specimen processed in the vacuum container, the storage container being disposed in the ambient gas flow over the outlet; a unit for controlling the operation of the transfer container, the unit being disposed between the storage container and the outlet; and an exhauster for exhausting a gas in the storage container.

In still another aspect of the present invention, the storage container includes a surrounding external wall and an opening through which the specimen is transferred, the surrounding external wall forming a substantially closed storage space and the opening communicating with the transfer container.

In still another aspect of the present invention, the opening faces the ambient gas flow.

In still another aspect of the present invention, the internal pressure of the storage space is lower than the internal pressure of the transfer container.

### BRIEF DESCRIPTION OF THE DRAWINGS

FIG. 1 is a schematic top view of a vacuum processing apparatus according to a first embodiment of the present invention;

FIG. 2 is an enlarged top view of an atmospheric section in the vacuum processing apparatus illustrated in FIG. 1;

FIG. 3A is a vertical sectional side view of an atmospheric transfer container illustrated in FIG. 2, viewed in the direction of arrow A in FIG. 2;

FIG. 3B is a vertical sectional front view of the atmospheric transfer container illustrated in FIG. 2, viewed from the bottom of FIG. 2 (viewed from the front of the vacuum processing apparatus);

FIG. 4A is a transverse sectional view of the second standby station illustrated in FIG. 3, viewed in the direction of arrow B in FIG. 3B;

FIG. 4B is a transverse sectional view of the second standby station, viewed in the direction of arrow C in FIG. 4A; and

FIG. 4C is a transverse sectional view of the second standby station, viewed in the direction of arrow D in FIG. 4A (viewed from the front of the vacuum processing apparatus).

### DESCRIPTION OF THE PREFERRED EMBODIMENTS

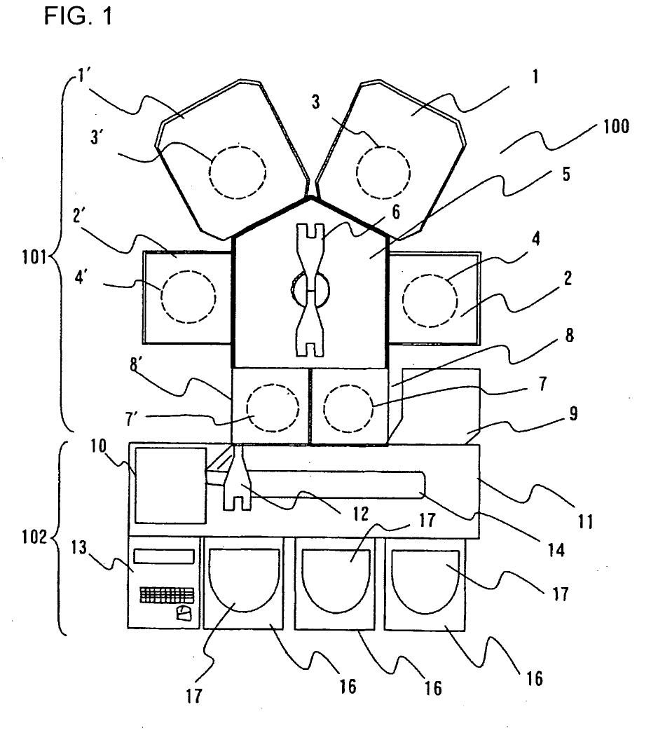

A first embodiment of the present invention is described below with reference to FIGS. 1 to 4.

FIG. 1 is a schematic top view of a vacuum processing apparatus according to a first embodiment of the present invention. Part of the apparatus is shown in transverse cross section.

A plasma processing apparatus 100 according to the present embodiment is divided broadly into a vacuum section 101 (an upper section in FIG. 1) and an atmospheric section 102 (a lower section in FIG. 1).

The atmospheric section 102 includes a plurality of cassette stages 16 on which a cassette 17 for storing a plurality of substrate specimens to be processed in the vacuum processing apparatus 100, such as semiconductor wafers, is placed. The atmospheric section 102 also includes an atmospheric transfer container 11 on which at least one cassette stage 16 is arranged in the horizontal direction on the front (lower position in FIG. 1) of the apparatus. The atmospheric transfer container 11 includes an atmospheric transfer chamber 15 through which a specimen in one of the cassettes 17 is transferred. Three cassettes 17 in FIG. 1 may be replaced with two cassettes 17 for processed wafers and an adjacent dummy cassette for a dummy wafer.

The vacuum section 101 includes a vacuum transfer container 5 having a generally polygonal cross-section (generally pentagon in the present embodiment) disposed in the center of the section and a plurality of vacuum containers on the side walls of the vacuum transfer container 5.

Specifically, etching units 1, 1′ each including a vacuum container containing a processing chamber for etching a specimen therein are disposed on two upper side walls of the vacuum transfer container 5 (at the rear of the vacuum processing apparatus). Although not shown in FIG. 1, the etching units 1, 1′ are divided broadly into a vacuum container, a processing container including an electric field and magnetic field generator for generating plasma in a processing chamber in the vacuum container, and a bed disposed under the processing container and housing a device required for the operation of the vacuum container and for etching in the processing chamber. Ashing units 2, 2′ each including a vacuum container containing a processing chamber for ashing a specimen therein are disposed on left and right side walls of the vacuum transfer container 5 (at the left and right of the vacuum processing apparatus). These ashing units 2, 2′ are also divided into an upper processing container and a lower bed. The vacuum containers in the etching units 1, 1′ and the ashing units 2, 2′ include specimen stages 3, 3′ and 4, 4′ on which a specimen is processed with plasma.

Load lock chambers or unload lock chambers 8, 8′ are disposed between the atmospheric transfer container 11 and the vacuum transfer container 5 so as to connect one and another. These chambers are vacuum containers through which a specimen is transferred. According to the present embodiment, the load lock chambers or unload lock chambers 8, 8′ contain a specimen before or after processing and are designed to have a predetermined pressure between a high vacuum pressure substantially equal to the internal pressure of the vacuum containers in the processing units (etching units 1, 1′ and ashing units 2, 2′) or the vacuum transfer container 5 and a substantially atmospheric pressure in the atmospheric transfer container 11. This structure allows a specimen to be transferred from the atmospheric section 102 to the vacuum section 101 and vice versa.

The load lock chambers and the unload lock chambers have the same function. Whether a specimen is transferred in only one direction or in both directions depends on requirements. The load lock. chambers and the unload lock chambers are hereinafter simply referred to as load lock chambers. In the load lock chambers 8, 8′, specimen stages 7, 7′ on which a specimen is placed are disposed in the respective vacuum containers, as in the etching units 1, 1′ and the ashing units 2, 2′.

In the vacuum processing apparatus 100 having such a structure, a specimen to be processed, such as a semiconductor wafer, is removed from one of the cassettes 17 with a robot arm 12 disposed in the atmospheric transfer chamber 15 in the atmospheric transfer container 11. The specimen is transferred through the atmospheric transfer chamber 15 and an opening on a rear wall of the atmospheric transfer container 11 to the load lock chamber 8 (or 8′). Then, the specimen is placed on a specimen stage 7 (or 7′) in the load lock chamber 8 (or 8′).

After the opening is closed, the load lock chamber 8 is evacuated to a predetermined pressure substantially equal to the internal pressure of the vacuum transfer container 5. After the pressure of the load lock chamber 8 reaches the predetermined pressure, an opening to the vacuum transfer container 5 is opened. The specimen is removed from the specimen stage 7 in the load lock chamber 8 with a robot arm 6 disposed in the vacuum transfer container 5. Then, the specimen is transferred through a vacuum transfer chamber in the vacuum transfer container 5 to a processing chamber in the vacuum container in one of the processing units, for example, the etching unit 1. Then, the specimen is placed on the specimen stage 3 in the vacuum container. After an opening between the vacuum container in the etching unit 1 and the vacuum transfer chamber in the vacuum transfer container 5 is closed with a closing mechanism, such as a gate valve, the specimen is etched in the vacuum container.

After etching is completed, the opening between the vacuum container in the etching unit 1 and the vacuum transfer chamber is opened. Then, the specimen is transferred in reverse order or in a reverse direction to that described above. Alternatively, the specimen is transferred to the ashing unit 2 (or 2′) and is subjected to ashing. Then, the specimen is transferred through the vacuum transfer container 5, the load lock chamber 8′ (or 8), and the atmospheric transfer chamber 15 in the atmospheric transfer container 11 to the original cassette 17.

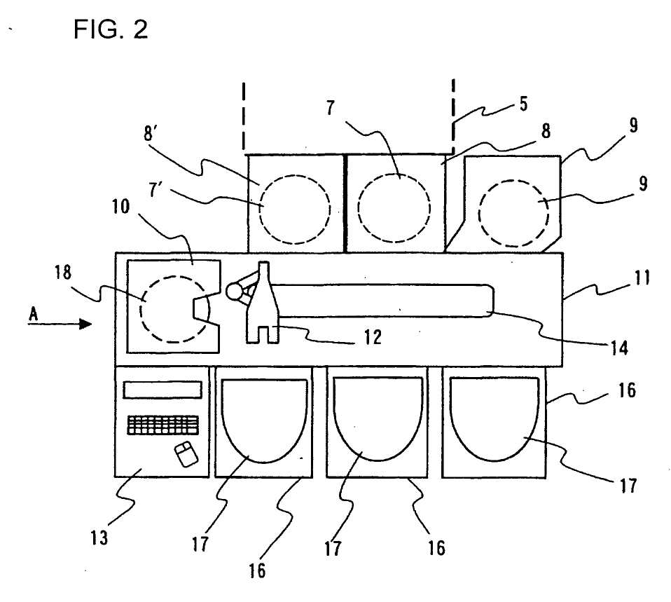

FIG. 2 is an enlarged top view of the atmospheric section in the vacuum processing apparatus illustrated in FIG. 1.

A plurality of cassettes 17 are arranged at almost the same height in the horizontal direction on the front of the atmospheric transfer container 11 (lower position of the atmospheric section 102 in FIG. 2). A user can enter a command or operate the vacuum processing apparatus through a console 13 at the front of the left end of the atmospheric transfer container 11 at almost the same height as the cassettes 17. In the following description, a part in which a reference numeral described above is cited will not be further explained.

The atmospheric transfer container 11 includes the atmospheric transfer chamber 15. The robot arm 12 can move in the atmospheric transfer chamber 15 in the horizontal direction and transfer a specimen between the cassettes 17 and the load lock chambers 8, 8′. The robot arm 12 travels at least parallel to the cassettes 17 along a guide rail 14 disposed in the atmospheric transfer chamber 15. The guide rail 14 has a length substantially equal to the distance between the left end and the right end of three cassettes 17 so that the robot arm 12 can put a wafer in or remove a wafer from these cassettes 17.

According to the present embodiment, a first standby station 9 for storing a wafer processed in the etching unit 1 is disposed at the upper right end of the atmospheric transfer container 11 (on the right rear face of the atmospheric transfer container 11 and at a middle height thereof). The first standby station 9 communicates with the atmospheric transfer container 11.

The first standby station 9 includes a cassette 18 (not shown) for storing at least one fewer wafer than the number of wafers stored in the cassettes 17. The first standby station 9 has an opening on the front thereof. The opening has the same height as a wafer storage space in the cassette 18 and the width equal to or more than the diameter of the wafers. Thus, the wafers can easily be stored or removed.

A second standby station 10 is disposed at the left end of the space inside the atmospheric transfer container 11. The second standby station 10 includes a cassette 18 having the same structure as in the first standby station 9.

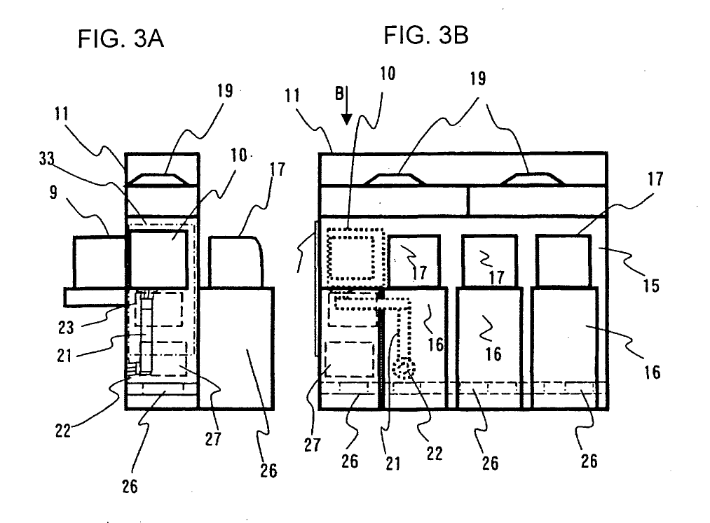

FIG. 3A is a vertical sectional side view of the atmospheric transfer container illustrated in FIG. 2, viewed in the direction of arrow A in FIG. 2. FIG. 3B is a vertical sectional front view of the atmospheric transfer container illustrated in FIG. 2, viewed from the bottom of FIG. 2 (viewed from the front of the vacuum processing apparatus).

The second standby station 10 is disposed at the left end of the atmospheric transfer container 11 in the middle in height. An aligner 23 is disposed under the second standby station 10. The aligner 23 adjusts the position of a specimen in the rotation direction about an axis perpendicular to the surface of the specimen before the specimen is transferred from one of the cassettes 17 to the load lock chamber 8 or 8′.

The vertical level of the cassette 18 in the second standby station 10 is the same as that of the top surfaces of the cassette stages 16 on which the cassettes 17 are disposed in front of the atmospheric transfer container 11 or the lower ends of the cassettes 17. In other words, the vertical level at which the cassette 18 in the second standby station 10 stores a specimen includes the vertical level of the top surfaces of the cassette stages 16 on which the cassettes 17 are disposed in front of the atmospheric transfer container 11 and the lower ends of specimen storages in the cassettes 17.

In particular, according to the present embodiment, the lower ends of the cassettes 17 (or the lower ends of specimen storages) or the top surfaces of the cassette stages 16 are positioned between a specimen-mounting face of the aligner 23 and the lower end of the second standby station 10 or the lowest wafer in the cassettes.

As described above, the second standby station 10 includes a cassette 18 for storing a specimen. The second standby station 10 has an opening on its right side in FIG. 3B for storing or removing a specimen, as described below. Other than the opening, the cassette 18 is surrounded by plates at the front and rear, the left side, and the top and bottom in FIG. 3B. That is, the plates constitute a container 24 for housing the cassette 18.

The second standby station 10 includes an exhaust port 20 in the bottom at the left of the cassette 18 in FIG. 3B (behind the cassette 18). The gas in the container 24 in the standby station 10 is aspirated and is exhausted from the exhaust port 20. The gas from the exhaust port 20 is exhausted from an exhaust vent 22 at the lower rear of the atmospheric transfer container 11 via an exhaust duct 21. The gas from the exhaust vent 22 is exhausted from a clean room where the apparatus is placed via another duct or pipe. While an aspirator or a pressure-reducing device, such as a vacuum pump, is placed outside the clean room in this embodiment, an evacuator, such as a fan, may be installed on the exhaust vent 22 to exhaust the gas in the second standby station 10 from the exhaust port 20 and the exhaust duct 21.

As illustrated in FIG. 3B, the atmospheric transfer container 11 has a generally rectangular parallelepiped shape. A plurality of fan units 19 for introducing an ambient gas outside the atmospheric transfer container 11 into the atmospheric transfer chamber 15 is placed inside the top of the atmospheric transfer container 11. According to the present embodiment, the atmospheric transfer chamber 15 in the atmospheric transfer container 11 has almost the same width as the atmospheric transfer container 11. The fan units 19 generate a gas current from the top to the bottom across the width of the atmospheric transfer chamber 15. A plurality of exhaust openings 26 is disposed in the lower part of the atmospheric transfer container 11 under the atmospheric transfer chamber 15 across the width of the atmospheric transfer chamber 15. The gas current in the atmospheric transfer chamber 15 flows out of the atmospheric transfer container 11 through these exhaust openings 26.

Because the ambient gas is introduced into the atmospheric transfer chamber 15 by the fan units 19, the atmospheric transfer chamber 15 has a pressure higher by a predetermined value than the ambient pressure outside the atmospheric transfer container 11. This positive pressure reduces an ambient gas outside flow into the atmospheric transfer chamber 15 even when the atmospheric transfer chamber 15 is exposed to the ambient gas outside, for example, during the removal of a cassette 17, thus reducing the contamination of the atmospheric transfer chamber 15 with dust and contaminating matter.

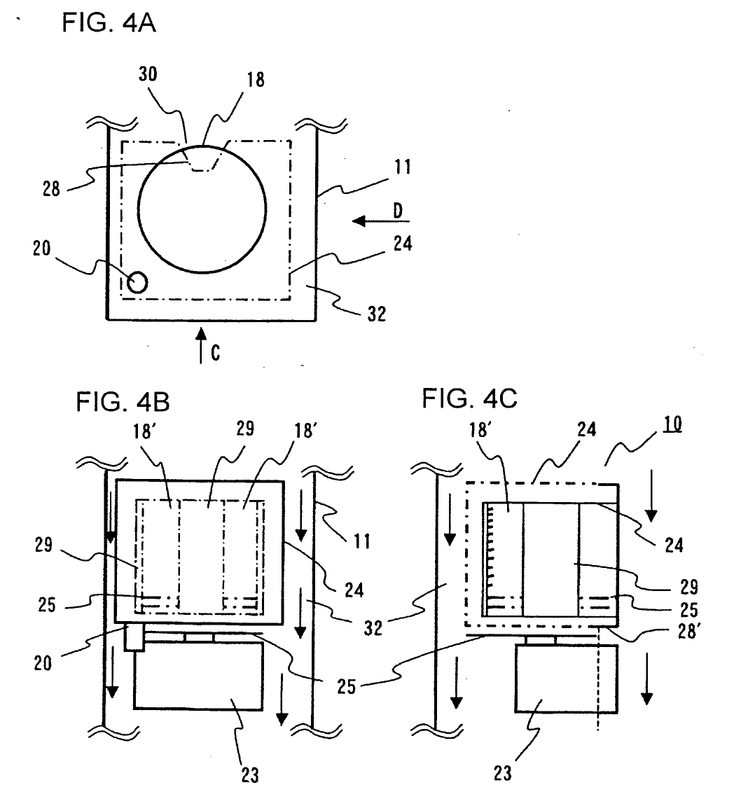

FIG. 4A is a transverse sectional view of the second standby station illustrated in FIG. 3, viewed in the direction of arrow B in FIG. 3B. FIG. 4B is a transverse sectional view of the second standby station, viewed in the direction of arrow C in FIG. 4A. FIG. 4C is a transverse sectional view of the second standby station, viewed in the direction of arrow D in FIG. 4A (viewed from the front of the vacuum processing apparatus).

As described above, the second standby station 10 includes the vessel 24 for housing the cassette 18. The vessel 24 has a generally rectangular parallelepiped shape and has an opening on a sidewall. The second standby station 10 is disposed over the aligner 23. The specimen-mounting face of the aligner 23 and the lower end of the second standby station 10 (or the lower end of the vessel 24) are vertically aligned with a predetermined gap therebetween. A specimen is transferred between the aligner 23 and the robot arm 12 through this gap.

The downward gas current flows in the direction of the arrow in FIG. 4B inside spaces between the sidewalls of the atmospheric transfer container 11 and the second standby station 10 and the aligner 23. In other words, the gas current generated by the fan units 19 flows downward through a gap 32 between the sidewalls (the left wall, the right wall, and the bottom wall in FIG. 4A) of the atmospheric transfer container 11 and the sidewalls of the vessel 24 and the sidewalls of the aligner 23.

The vessel 24 in the second standby station 10 has an opening 30 (at the top in FIG. 4A). The gas current also flows downward through the space in front of the opening 30. Thus, even if a reactive gas surrounding a processed specimen stored in the cassette 18 flows toward the atmospheric transfer chamber 15, the downward gas current sweeps the reactive gas downward, thus reducing the effects of the reactive gas on the robot arm 12 and other parts in the atmospheric transfer chamber 15, for example, a robot arm controller 27 disposed under the aligner 23.

Furthermore, the gas current flows through a gap between the second standby station 10 and the aligner 23. This also reduces the effects of a reactive gas or product entering the gap on the aligner 23 and the vessel 24 in the second standby station 10.

In addition, a reactive gas or an adhesive product in the vessel 24 is exhausted from the exhaust port 20 in the rear bottom of the vessel 24 behind the cassette 18. This gas aspiration causes a flow from the space around a specimen in the cassette 18 to the exhaust port 20 in the vessel 24. This flow prevents the reactive gas or product around the specimen from flowing from the second standby station 10 to the atmospheric transfer chamber 15.

As illustrated in FIGS. 4A to 4C, the cassette 18 has a generally cylindrical shape and stores a specimen. The vessel 24 has openings 18′ at the left and right rear behind the cassette 18 (at the left in FIG. 4C) across the height of the cassette 18 so as not to disturb the flow from the opening 30 to the exhaust port 20 in the vessel 24 or the space around the specimen. The openings 18′ are formed by three plate stays 29 having a height of wafers to be stored in the cassette 18.

The second standby station 10 can be removed from the atmospheric transfer chamber 15 or the atmospheric transfer container 11. That is, an access door 33, which allows an operator to directly handle the second standby station 10, is disposed approximately at the center of the left sidewall of the atmospheric transfer container 11.

The operator can handle the cassette 18 by opening the access door 33 and removing a rear panel 24′ of the vessel 24.

The rear panel 24′ is large enough to remove the cassette 18. Thus, the operator can remove the cassette 18 from the atmospheric transfer container 11 and can easily replace or clean the cassette 18. Furthermore, the operator can handle, for example, wipe the inside wall of the vessel 24. The operator can also remove the vessel 24 from the access door 33.

According to the present embodiment, the cassette 18 in the vessel 24 has substantially the same structure as the storage structure of the cassettes 17 on the atmospheric transfer container 11. The cassette 18 also has the same storage height and can store the same number of specimens as the cassettes 17. A top plate and a bottom plate of the cassette 18 have substantially the same shape as a disk substrate specimen and have a slightly larger diameter than the disk substrate specimen, thus covering the entire specimen. The cassette 18 includes a plurality of (three) vertical stays 29 as described above and a plurality of flanges provided on each stay 29. The plurality of flanges constitute a plurality of steps on which the edge of a wafer 25 is placed. The stays 29 are disposed along the perimeter of a stored specimen at substantially the same distance from the center of the specimen (concyclic). The number of steps of the flanges correspond to the number of specimens to be stored.

The top plate and the bottom plate of the vessel 24 have a notch 28 and a notch 28′ in the front center (at the top in FIG. 4A), respectively, to avoid the interference with a specimen transferring arm of the robot arm 12. As indicated by a broken line in FIG. 4C, the front end of a specimen 25 (right in the drawing) on the aligner 23 is located in a rearward position of the front end of the second standby station 10, in particular, the deepest portion of the notch 28′. This reduces the adverse effects of a product or gas from the vessel 24 while a specimen is placed on the aligner 23.

According to this embodiment, the second standby station 10 and the vessel 24 are placed in the downward gas current in the atmospheric transfer chamber 15. This prevents a reaction product or a reactive gas from a specimen stored in the standby station 10 from flowing into the atmospheric transfer container 11 and the atmospheric transfer chamber 15.

In particular, the second standby station 10 according to the present embodiment has the opening 30 for transferring a specimen. The opening 30 is also exposed to the downward gas current. This further prevents the diffusion of a reactive gas and a reaction product.

Furthermore, the gas in the vessel 24 flows out from the exhaust port 20 in the rear bottom of the vessel 24 (opposite to the opening 30 across the cassette 18). Thus, the vessel 24 has a pressure lower than the ambient pressure in the atmospheric transfer container 11. Thus, the atmospheric transfer chamber 15 has a higher pressure than the vessel 24. While the atmospheric transfer chamber 15 has a higher positive pressure than the ambient atmosphere of the atmospheric transfer container 11, the vessel 24 has a low negative pressure. This prevents a product or gas in the vessel 24 from flowing into the atmospheric transfer chamber 15, reducing contamination and corrosion of the atmospheric transfer container 11.

Thus, the second standby station 10 can be placed over the aligner 23 in the atmospheric transfer container 11. This minimizes an increase in the footprint of the vacuum processing apparatus 100 in a structure, such as a clean room, allowing efficient utilization of the floor space. Furthermore, a secured working space improves the working efficiency and therefore the processing efficiency.

What is claimed is:

1. A vacuum processing apparatus comprising:
a vacuum container in which a specimen is processed with plasma generated from a processing gas supplied to the vacuum container;
a transfer container through which the specimen processed in the vacuum container is transferred, the transfer container being coupled to the vacuum container under ambient pressure;
a blower for generating an ambient gas flow in the transfer container and an outlet disposed on the transfer container;
a storage container for storing the specimen processed in the vacuum container, the storage container being disposed in the ambient gas flow in the transfer container; and
an exhauster for exhausting a gas in the storage container.

2. A vacuum processing apparatus comprising:
a vacuum container in which a specimen is processed with plasma generated from a processing gas supplied to the vacuum container;
a transfer container through which the specimen processed in the vacuum container is transferred, the transfer container being coupled to the vacuum container under ambient pressure;
a stage on which the specimen is placed, the stage being disposed outside the transfer container;
a robot for putting the specimen into and removing the specimen from a cassette that stores the specimen and for transferring the specimen in the transfer container, the robot being disposed in the transfer container and the cassette being disposed on the stage;
a blower for generating an ambient gas flow in the transfer container and an outlet disposed on the transfer container;
a storage container for storing the specimen processed in the vacuum container, the storage container being disposed in the ambient gas flow over the outlet;
a unit for controlling the operation of the transfer container, the unit being disposed between the storage container and the outlet; and
an exhauster for exhausting a gas in the storage container.

3. The vacuum processing apparatus according to claim 1 or 2, wherein the storage container comprises a surrounding external wall and an opening through which the specimen is transferred, the surrounding external wall forming a substantially closed storage space and the opening communicating with the transfer container.

4. The vacuum processing apparatus according to claim 1 or 2, wherein the opening faces the ambient gas flow.

5. The vacuum processing apparatus according to any of claims 1 or 2, wherein the internal pressure of the storage space is lower than the internal pressure of the transfer container.

6. The vacuum processing apparatus according to claim 3, wherein the internal pressure of the storage space is lower than the internal pressure of the transfer container.
